(19) United States
(12) Patent Application Publication
(10) Pub. No.: US 2026/0198229 A1
(43) Pub. Date: Jul. 9, 2026

(54) MAGNETIC TUNNEL JUNCTION DEVICE UTILIZING VOLTAGE-CONTROLLED MAGNETIC ANISOTROPY EFFECT AND ITS MANUFACTURING METHOD

(71) Applicant: RESEARCH & BUSINESS FOUNDATION SUNGKYUNKWAN UNIVERSITY, Suwon-si (KR)

(72) Inventors: Saeroonter OH, Seoul (KR); Stanislav SIN, Ansan-si (KR)

(21) Appl. No.: 19/438,742

(22) Filed: Jan. 2, 2026

(30) Foreign Application Priority Data
Jan. 7, 2025 (KR) 10-2025-0002354

(51) Int. Cl. H10N 50/10; G11C 11/16; H10N 50/01; H10N 50/85

(52) U.S. Cl. CPC H10N 50/10; G11C 11/161; G11C 11/1673; G11C 11/1675; H10N 50/01; H10N 50/85

(57) ABSTRACT

Provided is a magnetic tunnel junction device. The magnetic tunnel junction device includes: a free layer having a magnetization direction that is switchable; a tunneling barrier layer disposed on the free layer and including a metal oxide; a first fixed layer disposed on the tunneling barrier layer and having a magnetization direction fixed in a first direction; and a second fixed layer disposed on the tunneling barrier layer to be spaced apart from the first fixed layer, and having a magnetization direction fixed in a second direction that is opposite to the first direction.

### BACKGROUND OF THE INVENTION

### 1. Field of the Invention

The present invention relates to a magnetic tunnel junction device and a method for manufacturing the same, and more specifically, to a magnetic tunnel junction device utilizing a voltage-controlled magnetic anisotropy (VCMA) effect and a method for manufacturing the same.

### 2. Description of the Related Art

Spintronics devices are attracting attention as a promising solution to future computing and memory technologies. The spintronics devices have non-volatile properties, resistance to radiation, and compatibility with CMOS back-end processes. However, conventional current-driven spintronics devices have problems of long switching delay time and high power consumption.

Recent advances in magnetoelectronics, particularly in the field of voltage-controlled magnetism, have suggested solutions to this problem. In particular, devices to which a voltage-controlled magnetic anisotropy (VCMA) effect is applied may control interface-based perpendicular magnetic anisotropy energy, thereby easily solving the problems of the conventional current-driven spintronics devices. However, most of the voltage-controlled magnetic anisotropy (VCMA)-based switching methods require a pre-read operation, an accurate pulse width control, and a high write error rate. Accordingly, the present invention provides a magnetic tunnel junction device utilizing a voltage-controlled magnetic anisotropy (VCMA) effect, and having a reduced write error rate without requiring a pre-read operation and an accurate pulse width control.

### SUMMARY OF THE INVENTION

One technical problem to be solved by the present invention is to provide a magnetic tunnel junction device and a method for manufacturing the same.

Another technical problem to be solved by the present invention is to provide a magnetic tunnel junction device utilizing a voltage-controlled magnetic anisotropy effect and a method for manufacturing the same.

Still another technical problem to be solved by the present invention is to provide a magnetic tunnel junction device without requiring a pre-read operation and a method for manufacturing the same.

Still another technical problem to be solved by the present invention is to provide a magnetic tunnel junction device without requiring an accurate pulse width control and a method for manufacturing the same.

Still another technical problem to be solved by the present invention is to provide a magnetic tunnel junction device with an increased write speed and a method for manufacturing the same.

Still another technical problem to be solved by the present invention is to provide a magnetic tunnel junction device with a reduced write error rate and a method for manufacturing the same.

The technical problems to be solved by the present invention are not limited to those described above.

To solve the above technical problems, the present invention provides a magnetic tunnel junction device.

According to one embodiment, the magnetic tunnel junction device may include: a free layer having a magnetization direction that is switchable; a tunneling barrier layer disposed on the free layer and including a metal oxide; a first fixed layer disposed on the tunneling barrier layer and having a magnetization direction fixed in a first direction; and a second fixed layer disposed on the tunneling barrier layer to be spaced apart from the first fixed layer, and having a magnetization direction fixed in a second direction that is opposite to the first direction.

According to one embodiment, when a current flows from the first fixed layer to the free layer, the magnetization direction of the free layer may be switched to be parallel to the magnetization direction of the first fixed layer, and when the current flows from the second fixed layer to the free layer, the magnetization direction of the free layer may be switched to be parallel to the magnetization direction of the second fixed layer.

According to one embodiment, when a current flows from the first fixed layer or the second fixed layer to the free layer, a voltage may be induced between a first boundary surface, which is defined as a boundary surface between the free layer and the tunneling barrier layer, and a second boundary surface, which is defined as a boundary surface between the first fixed layer or the second fixed layer and the tunneling barrier layer, so that the magnetization direction of the free layer may be switched, in accordance with <Equation 1> below.

$${V}_{ox} = {I}_{s} {R}_{MTJ} \qquad Equation 1$$

(Vₒₓ: Voltage induced between the first boundary surface and the second boundary surface, Iₛ: Current flowing from the first fixed layer or the second fixed layer to the free layer, and R_{MTJ}: Resistance of the tunneling barrier layer)

According to one embodiment, when the voltage is induced between the first boundary surface and the second boundary surface, magnetic anisotropy energy of the first boundary surface, which is calculated according to <Equation 2> below, may be reduced so that the magnetization direction of the free layer may be switched.

$$Δ E = \frac{ξ}{{t}_{fl}} \frac{{V}_{ox}}{{t}_{ox}} \qquad Equation 2$$

(ΔE: Magnetic anisotropy energy reduction of the first boundary surface, ξ: Voltage-controlled magnetic anisotropy coefficient, t_{fl}: Thickness of the free layer, Vₒₓ: Voltage induced between the first boundary surface and the second boundary surface, tₒₓ: Thickness of the tunneling barrier layer)

According to one embodiment, as the magnetic anisotropy energy of the first boundary surface is reduced, energy asymmetry may be formed between the free layer and the first fixed layer or between the free layer and the second fixed layer.

According to one embodiment, a read operation may be performed to confirm the magnetization direction of the free layer by flowing a current lower than a critical current, which switches the magnetization direction of the free layer, from the first fixed layer to the free layer.

According to one embodiment, the magnetic tunnel junction device may further include a spacer disposed on the tunneling barrier layer and including a metal, in which the first fixed layer and the second fixed layer are disposed on the spacer to be spaced apart from each other.

According to one embodiment, the spacer may include one of copper (Cu) and ruthenium (Ru).

According to one embodiment, the free layer, the first fixed layer, and the second fixed layer may include one of cobalt nickel (CoNi), cobalt iron boride (CoFeB), cobalt chromium (CoCr), cobalt iron (CoFe), cobalt platinum (CoPt), iron platinum (FePt), iron boride (FeB), cobalt boride (CoB), and cobalt iron aluminum (CeFeAl).

According to one embodiment, the tunneling barrier layer may include one of magnesium oxide (MgO), aluminum oxide (Al₂O₃), magnesium aluminum oxide (MgAlO), hafnium oxide (HfO₂), zirconium oxide (ZrO₂), zinc oxide (ZnO₂), and titanium oxide (TiO₂).

According to another embodiment, the magnetic tunnel junction device may include: a first magnetic tunnel junction structure including a free layer having a magnetization direction that is switchable, a tunneling barrier layer disposed on the free layer, a spacer disposed on the tunneling barrier layer, and a first fixed layer disposed on the spacer and having a magnetization direction fixed in a first direction; and a second magnetic tunnel junction structure including the free layer, the tunneling barrier layer, the spacer, and a second fixed layer disposed on the tunneling barrier layer and having a magnetization direction fixed in a second direction, in which the first magnetic tunnel junction structure and the second magnetic tunnel junction structure may share the free layer, the tunneling barrier layer, and the spacer.

According to the other embodiment, the magnetization direction of the free layer may be switched to the first direction or the second direction according to one of a case where a current flows from the first fixed layer to the free layer and a case where the current flows from the second fixed layer to the free layer.

According to the other embodiment, when the current flows from the first fixed layer to the free layer, the magnetization direction of the free layer may be switched to the first direction, and when the current flows from the second fixed layer to the free layer, the magnetization direction of the free layer may be switched to the second direction.

To solve the above technical problems, the present invention provides a method for manufacturing a magnetic tunnel junction device.

According to one embodiment, the method for manufacturing a magnetic tunnel junction device may include: preparing a stack structure in which a free layer including a ferromagnetic material, a tunneling barrier layer including an oxide, a spacer including a metal, and a fixed layer including a ferromagnetic material are sequentially stacked; providing a mask on the fixed layer, in which the mask exposes a central region of the fixed layer and covers an edge region of the fixed layer; and exposing the spacer to an outside through the central region of the fixed layer by etching the central region of the fixed layer using the mask.

According to one embodiment, the method for manufacturing a magnetic tunnel junction device may further include performing a heat treatment by applying an external magnetic field to the fixed layer in which the central region is etched, after the exposing of the spacer to the outside through the central region of the fixed layer by etching the central region of the fixed layer using the mask.

The magnetic tunnel junction device according to the embodiment of the present invention may include: a free layer having a magnetization direction that is switchable; a tunneling barrier layer disposed on the free layer and including a metal oxide; a first fixed layer disposed on the tunneling barrier layer and having a magnetization direction fixed in a first direction; and a second fixed layer disposed on the tunneling barrier layer to be spaced apart from the first fixed layer, and having a magnetization direction fixed in a second direction that is opposite to the first direction.

In the magnetic tunnel junction device according to the embodiment, a voltage may be induced (a voltage-controlled magnetic anisotropy effect may be generated) between two ends (upper and lower ends) of the tunneling barrier layer as the current flows from the first fixed layer or the second fixed layer to the free layer, and the energy asymmetry may be formed between the free layer and the fixed layer (the first fixed layer or the second fixed layer), so that the magnetization direction of the free layer may be switched, and when the current flows from the first fixed layer to the free layer, the magnetization direction of the free layer may be switched to be parallel to the magnetization direction of the first fixed layer, and when the current flows from the second fixed layer to the free layer, the magnetization direction of the free layer may be switched to be parallel to the magnetization direction of the second fixed layer.

Accordingly, the magnetic tunnel junction device according to the above embodiment may be driven at low power, may improve the reliability of switching, and may not require an accurate pulse width control, thereby simplifying the complexity of a peripheral circuit through a simple control pulse. In addition, since the read operation may be performed without a pre-read operation, a speed of a write operation may be increased and an error rate may be reduced, and thus the data throughput of the memory may be easily increased when the data is written in a data-intensive application such as ML/AI.

### BRIEF DESCRIPTION OF THE DRAWINGS

FIG. 1 is a view for explaining a structure of a magnetic tunnel junction device according to an embodiment of the present invention.

FIG. 2 is a view for explaining a process in which a magnetization direction of a free layer in the magnetic tunnel junction device according to the present invention is switched to be parallel to a magnetization direction of a first fixed layer.

FIG. 3 is a view for explaining a process in which the magnetization direction of the free layer in the magnetic tunnel junction device according to the present invention is switched to be parallel to a magnetization direction of a second fixed layer.

FIGS. 4 and 5 are energy schematic views for explaining a switching method of the magnetic tunnel junction device according to the embodiment of the present invention.

FIGS. 6 to 8 are views for explaining a method for manufacturing a magnetic tunnel junction device according to the embodiment of the present invention.

FIG. 9 is a view for explaining an equivalent resistance circuit of the magnetic tunnel junction device according to the embodiment of the present invention.

FIG. 10 is a view for explaining a voltage distribution in the magnetic tunnel junction device according to the embodiment of the present invention.

FIG. 11 is a view for explaining a change in a magnetization direction over time of the magnetic tunnel junction device according to the embodiment of the present invention.

FIG. 12 is a view for explaining an energy contour map of the magnetic tunnel junction device according to the embodiment of the present invention.

FIG. 13 is a view for explaining a switching time and switching energy of the magnetic tunnel junction device according to the embodiment of the present invention.

FIG. 14 is a view for comparing the magnetic tunnel junction device according to the embodiment of the present invention with devices having different switching methods.

### DETAILED DESCRIPTION OF THE INVENTION

Hereinafter, preferred embodiments of the present invention will be described in detail with reference to the accompanying drawings. However, the present invention may be embodied in different forms and should not be construed as limited to the embodiments set forth herein. Rather, the embodiments introduced herein are provided so that the disclosed contents may be thorough and complete and the spirit of the present invention may be sufficiently conveyed to those skilled in the art.

In the present specification, it will be understood that when an element is referred to as being “on” another element, it may be formed directly on the other element or intervening elements may be present. In the drawings, the thicknesses of layers and regions are exaggerated for clarity.

In addition, it will be also understood that although the terms first, second, third, etc. may be used herein to describe various elements, these elements should not be limited by these terms. These terms are only used to distinguish one element from another element. Thus, a first element in some embodiments may be termed a second element in other embodiments without departing from the teachings of the present invention. Embodiments explained and illustrated herein include their complementary counterparts. As used herein, the term “and/or” includes any and all combinations of one or more of the associated listed elements.

The singular expression also includes the plural meaning as long as it does not differently mean in the context. In addition, the terms “comprise”, “have” etc., of the description are used to indicate that there are features, numbers, steps, elements, or combinations thereof, and they should not exclude the possibilities of combination or addition of one or more features, numbers, operations, elements, or a combination thereof. Furthermore, it will be understood that when an element is referred to as being “connected” or “coupled” to another element, it may be directly connected or coupled to the other element or intervening elements may be present.

In addition, when detailed descriptions of related known functions or constitutions are considered to unnecessarily cloud the gist of the present invention in describing the present invention below, the detailed descriptions will not be included.

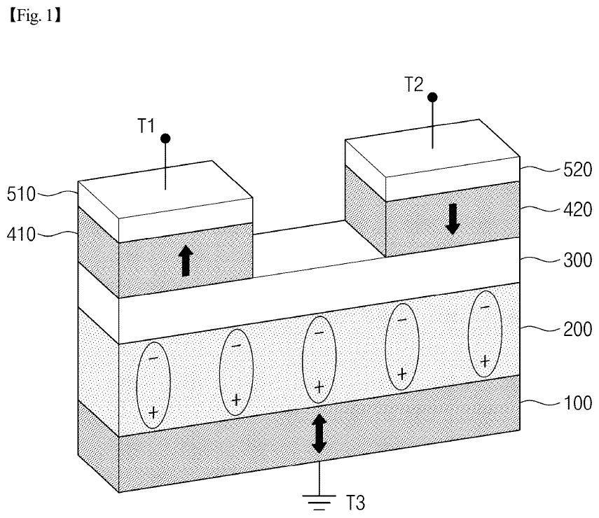

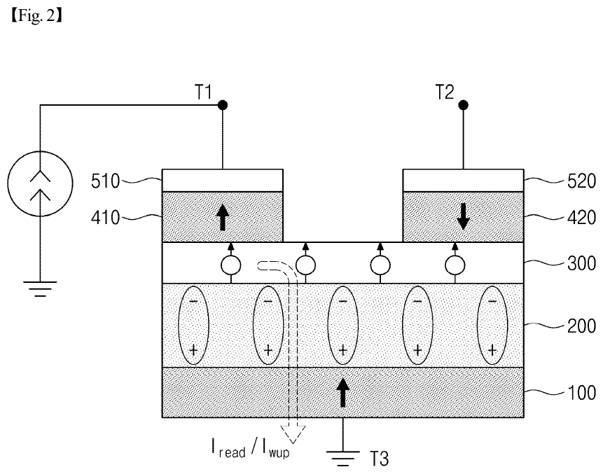

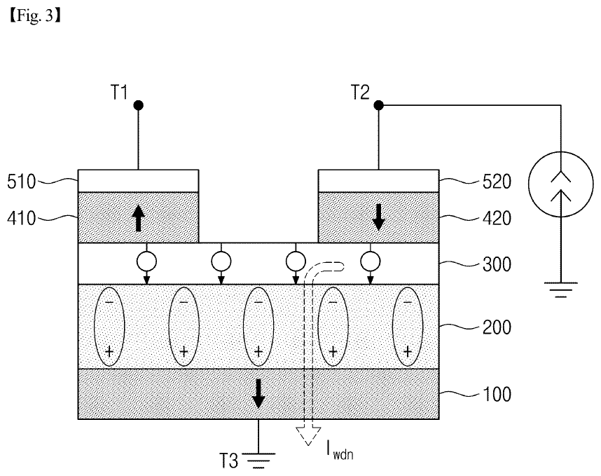

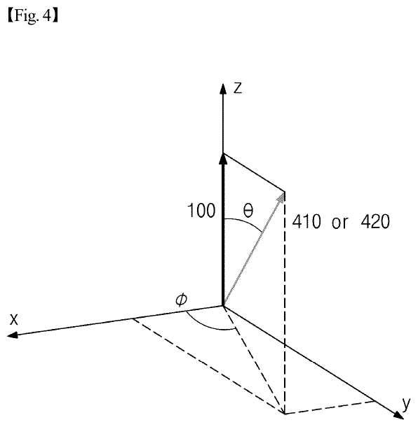

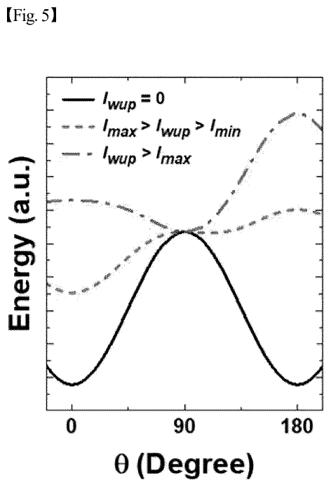

FIG. 1 is a view for explaining a structure of a magnetic tunnel junction device according to an embodiment of the present invention, FIG. 2 is a view for explaining a process in which a magnetization direction of a free layer in the magnetic tunnel junction device according to the present invention is switched to be parallel to a magnetization direction of a first fixed layer, FIG. 3 is a view for explaining a process in which the magnetization direction of the free layer in the magnetic tunnel junction device according to the present invention is switched to be parallel to a magnetization direction of a second fixed layer, and FIGS. 4 and 5 are energy schematic views for explaining a switching method of the magnetic tunnel junction device according to the embodiment of the present invention.

Referring to FIG. 1, the magnetic tunnel junction device according to the embodiment of the present invention may include a free layer 100, a tunneling barrier layer 200, a first spacer 300, a first fixed layer 410, a second fixed layer 420, a 2-1^{st} spacer 510, and a 2-2^{nd} spacer 520. Hereinafter, the respective components will be described.

A magnetization direction of the free layer 100 may be switched. That is, the magnetization direction of the free layer 100 may be changed. According to one embodiment, the free layer 100 may include a ferromagnetic material and may have a thickness of 1 nm to 3 nm. For example, the ferromagnetic material may include one of cobalt nickel (CoNi), cobalt iron boride (CoFeB), cobalt chromium (CoCr), cobalt iron (CoFe), cobalt platinum (CoPt), iron platinum (FePt), iron boride (FeB), cobalt boride (CoB), and cobalt iron aluminum (CeFeAl).

The tunneling barrier layer 200 may be disposed on the free layer 100. According to one embodiment, the tunneling barrier layer 200 may include a metal oxide. According to one embodiment, the tunnel barrier layer 200 may include an oxide and may have a thickness of 1 nm to 2 nm. According to one embodiment, the tunneling barrier layer 200 may include one of magnesium oxide (MgO), aluminum oxide (Al₂O₃), magnesium aluminum oxide (MgAlO), hafnium oxide (HfO₂), zirconium oxide (ZrO₂), zinc oxide (ZnO₂), and titanium oxide (TiO₂). According to another embodiment, the tunneling barrier layer 200 may include a structure in which a plurality of layers are stacked. For example, the tunneling barrier layer 200 may have a stack structure of Mg/MgO, MgO/Mg, MgO/MgAlO, MgAlO/MgO, Mg/MgAlO/Mg, MgO/MgAlO/MgO, MgAlO/MgO/MgAlO, or the like.

The first spacer 300 may be disposed on the tunneling barrier layer 200. The first spacer 300 may uniformly distribute a voltage from the first fixed layer 410 or the second fixed layer 420 to the tunneling barrier layer 200. According to one embodiment, the first spacer 300 may include a metal. For example, the first spacer 300 may include copper (Cu) or ruthenium (Ru), and may have a thickness of 1 nm to 1.5 nm.

The first fixed layer 410 and the second fixed layer 420 may be disposed on the first spacer 300, and may be spaced apart from each other. According to one embodiment, the first fixed layer 410 may be disposed on one side of the first spacer 300, whereas the second fixed layer 420 may be disposed on the other side of the first spacer 300. Accordingly, a central region of the first spacer 300 may be exposed to an outside. According to one embodiment, both the first fixed layer 410 and the second fixed layer 420 may include a ferromagnetic material and may have a thickness of 1 nm to 2 nm. For example, the ferromagnetic material may include one of cobalt nickel (CoNi), cobalt iron boride (CoFeB), cobalt chromium (CoCr), cobalt iron (CoFe), cobalt platinum (CoPt), iron platinum (FePt), iron boride (FeB), cobalt boride (CoB), and cobalt iron aluminum (CeFeAl).

Unlike the free layer 100, the magnetization directions of the first fixed layer 410 and the second fixed layer 420 may be fixed. According to one embodiment, the magnetization direction of the first fixed layer 410 may be fixed in a first direction. For example, the first direction may be defined as an upward direction UP from the free layer 100 to the first fixed layer 410. Alternatively, the magnetization direction of the second fixed layer 420 may be fixed in a second direction opposite to the first direction. For example, the second direction may be defined as a downward direction DN from the second fixed layer 420 to the free layer 100.

The 2-1^{st} spacer 510 may be disposed on the first fixed layer 410, and the 2-2^{nd} spacer 520 may be disposed on the second fixed layer 420. According to one embodiment, the 2-1^{st} spacer 510 and the 2-2^{nd} 520 may include tungsten (W) and may have a thickness of 0.15 nm to 0.3 nm.

According to one embodiment, the first fixed layer 410 may be electrically connected to a first terminal T1, the second fixed layer 420 may be electrically connected to a second terminal T2, and the free layer 100 may be electrically connected to a third terminal T3.

According to one embodiment, the free layer 100, the tunneling barrier layer 200, the spacer 300, and the first fixed layer 410 may be defined as a first magnetic tunnel junction structure, and the free layer 100, the tunneling barrier layer 200, the spacer 300, and the second fixed layer 420 may be defined as a second magnetic tunnel junction structure. In other words, the first magnetic tunnel junction structure and the second magnetic tunnel junction structure may share the free layer 100, the tunneling barrier layer 200, and the spacer 300 and may be disposed horizontally.

As shown in FIG. 2, when a current flows from the first fixed layer 410 to the free layer 100, the magnetization direction of the free layer 100 may be switched to be parallel to the magnetization direction of the first fixed layer 410. That is, when the current flows from the first fixed layer 410 to the free layer 100, the magnetization direction of the free layer 100 may be switched to the first direction UP to be parallel to the magnetization direction of the first fixed layer 410.

On the other hand, as shown in FIG. 3, when the current flows from the second fixed layer 420 to the free layer 100, the magnetization direction of the free layer 100 may be switched to be parallel to the magnetization direction of the second fixed layer 420. That is, when the current flows from the second fixed layer 420 to the free layer 100, the magnetization direction of the free layer 100 may be switched to the second direction DN to be parallel to the magnetization direction of the second fixed layer 420.

When the current flows from the first fixed layer 410 or the second fixed layer 420 to the free layer 100, a voltage may be induced between a first boundary surface, which is defined as a boundary surface between the free layer 100 and the tunneling barrier layer 200, and a second boundary surface, which is defined as a boundary surface between the first fixed layer 410 or the second fixed layer 420 and the tunneling barrier layer 200, more specifically, a boundary surface between the spacer 300 and the tunneling barrier layer 200, in accordance with <Equation 1> below. That is, when the current flows from the first fixed layer 410 or the second fixed layer 420 to the free layer 100, the voltage may be induced between two ends (upper and lower ends) of the tunneling barrier layer 200. In other words, when the current flows from the first fixed layer 410 or the second fixed layer 420 to the free layer 100, a voltage-controlled magnetic anisotropy effect may be generated.

$${V}_{ox} = {I}_{s} {R}_{MTJ} \qquad Equation 1$$

(Vₒₓ: Voltage induced between the first boundary surface and the second boundary surface, Iₛ: Current flowing from the first fixed layer or the second fixed layer to the free layer, and R_{MTJ}: Resistance of the tunneling barrier layer)

In addition, when the voltage is induced between the first boundary surface and the second boundary surface, magnetic anisotropy energy of the first boundary surface, which is calculated according to <Equation 2> below, may be reduced.

$$Δ E = \frac{ξ}{{t}_{fl}} \frac{{V}_{ox}}{{t}_{ox}} \qquad Equation 2$$

(ΔE: Magnetic anisotropy energy reduction of the first boundary surface, ξ: Voltage-controlled magnetic anisotropy coefficient, t_{f1}: Thickness of the free layer, Vₒₓ: Voltage induced between the first boundary surface and the second boundary surface, tₒₓ: Thickness of the tunneling barrier layer)

In addition, as the magnetic anisotropy energy of the first boundary surface is reduced, energy asymmetry may be formed between the free layer 100 and the first fixed layer 410 or between the free layer 100 and the second fixed layer 420, as shown in FIG. 4.

That is, in the magnetic tunnel junction device according to the embodiment, the voltage may be induced (the voltage-controlled magnetic anisotropy effect may be generated) between two ends (upper and lower ends) of the tunneling barrier layer 200 as the current flows from the first fixed layer 410 or the second fixed layer 420 to the free layer 100, and the energy asymmetry may be formed between the free layer 100 and the fixed layer 410 or 420, so that the magnetization direction of the free layer 100 may be switched, and when the current flows from the first fixed layer 410 to the free layer 100, the magnetization direction of the free layer 100 may be switched to be parallel to the magnetization direction of the first fixed layer 410, and when the current flows from the second fixed layer 420 to the free layer 100, the magnetization direction of the free layer 100 may be switched to be parallel to the magnetization direction of the second fixed layer 420.

Accordingly, the magnetic tunnel junction device according to the above embodiment may be driven at low power, may improve the reliability of switching, and may not require an accurate pulse width control, thereby simplifying the complexity of a peripheral circuit through a simple control pulse. In addition, since the read operation may be performed without a pre-read operation, a speed of a write operation may be increased and an error rate may be reduced, and thus the data throughput of the memory may be easily increased when the data is written in a data-intensive application such as ML/AI.

According to one embodiment, a read operation may be performed to confirm the magnetization direction of the free layer 100 by flowing the current, which is lower than a critical current, from the first fixed layer 410 to the free layer 100. The critical current may be defined as a current capable of switching the magnetization direction of the free layer 100.

In addition, as shown in FIG. 5, when a current having an appropriate magnitude flows from the first fixed layer 410 to the free layer 100, a parallel state is written due to energy asymmetry (a dashed line/black line in FIG. 5 indicates an initial state), whereas when an excessive current flows, an energy pole is formed vertically in the middle, and thus deterministic switching may be impossible (a blue dotted line in FIG. 5).

Hereinabove, the magnetic tunnel junction device according to the embodiment of the present invention has been described. Hereinafter, a method for manufacturing a magnetic tunnel junction device according to the embodiment of the present invention will be described.

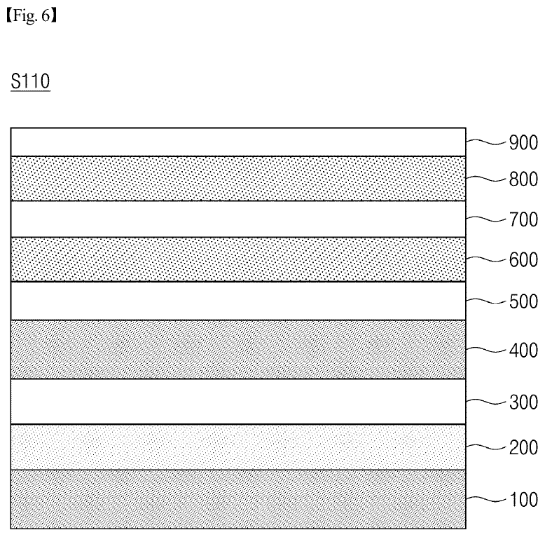

FIGS. 6 to 8 are views for explaining a method for manufacturing a magnetic tunnel junction device according to the embodiment of the present invention.

Referring to FIG. 6, a stack structure, in which the free layer 100, the tunneling barrier layer 200, the first spacer 300, a fixed layer 400, the second spacer 500, a first synthetic antiferromagnetic composite layer 600, a third spacer 700, a second synthetic antiferromagnetic composite layer 800, and a capping layer 900 are sequentially stacked, may be prepared (S110).

The free layer 100 may include a ferromagnetic material and may be formed to have a thickness of 1 nm to 3 nm. According to one embodiment, the free layer 100 may be formed using a sputtering method. For example, the ferromagnetic material may include one of cobalt nickel (CoNi), cobalt iron boride (CoFeB), cobalt chromium (CoCr), cobalt iron (CoFe), cobalt platinum (CoPt), iron platinum (FePt), iron boride (FeB), cobalt boride (CoB), and cobalt iron aluminum (CeFeAl).

The tunneling barrier layer 200 may be formed on the free layer 100. According to one embodiment, the tunneling barrier layer 200 may include an oxide and may be formed to have a thickness of 1 nm to 2 nm. According to one embodiment, the tunneling barrier layer 200 may be formed using a sputtering method. According to one embodiment, the tunneling barrier layer 200 may include one of magnesium oxide (MgO), aluminum oxide (Al₂O₃), magnesium aluminum oxide (MgAlO), hafnium oxide (HfO₂), zirconium oxide (ZrO₂), zinc oxide (ZnO₂), and titanium oxide (TiO₂). According to another embodiment, the tunneling barrier layer 200 may include a structure in which a plurality of layers are stacked. For example, the tunneling barrier layer 200 may have a stacked structure of Mg/MgO, MgO/Mg, MgO/MgAlO, MgAlO/MgO, Mg/MgAlO/Mg, MgO/MgAlO/Mg, MgAlO/MgO/MgAlO, or the like.

The first spacer 300 may be formed on the tunneling barrier layer 200. According to one embodiment, the first spacer 300 may include copper (Cu) or ruthenium (Ru), and may be formed to have a thickness of 1 nm to 1.5 nm. According to one embodiment, the first spacer 300 may be formed using a sputtering method.

The fixed layer 400 may be formed on the first spacer 300. According to one embodiment, the fixed layer 400 may include a ferromagnetic material and may be formed to have a thickness of 1 nm to 2 nm. According to one embodiment, the fixed layer 400 may be formed using a sputtering method. For example, the ferromagnetic material may include one of cobalt nickel (CoNi), cobalt iron boride (CoFeB), cobalt chromium (CoCr), cobalt iron (CoFe), cobalt platinum (CoPt), iron platinum (FePt), iron boride (FeB), cobalt boride (CoB), and cobalt iron aluminum (CeFeAl).

The second spacer 500 may be formed on the fixed layer 400. According to one embodiment, the second spacer 500 may include tungsten (W), and may be formed to have a thickness of 0.15 nm to 0.3 nm. According to one embodiment, the second spacer 500 may be formed using a sputtering method.

The first synthetic antiferromagnetic composite layer 600 may be formed on the second spacer 500. According to one embodiment, the first synthetic antiferromagnetic composite layer 600 may include cobalt and platinum (Co/Pt). For example, the first synthetic antiferromagnetic composite layer 600 may have a structure in which a platinum (Pt) layer having a thickness of 0.2 nm is stacked on a cobalt (Co) layer having a thickness of 0.5 nm. According to one embodiment, the first synthetic antiferromagnetic composite layer 600 may be formed using a sputtering method.

The third spacer 700 may be formed on the first synthetic antiferromagnetic composite layer 600. According to one embodiment, the third spacer 700 may include ruthenium (Ru), and may be formed to have a thickness of 0.85 nm. According to one embodiment, the third spacer 700 may be formed using a sputtering method.

The second synthetic antiferromagnetic composite layer 800 may be formed on the third spacer 700. According to one embodiment, the second synthetic antiferromagnetic composite layer 800 may include cobalt and platinum (Co/Pt). For example, the second synthetic antiferromagnetic composite layer 800 may have a structure in which a platinum (Pt) layer having a thickness of 0.2 nm is stacked on a cobalt (Co) layer having a thickness of 0.5 nm. According to one embodiment, the second synthetic antiferromagnetic composite layer 800 may be formed using a sputtering method.

The capping layer 900 may be formed on the second synthetic antiferromagnetic composite layer 800. According to one embodiment, the capping layer 900 may include tantalum (Ta) and may be formed to have a thickness of 2 nm. According to one embodiment, the capping layer 900 may be formed using a sputtering method.

Although the sputtering method has been described as a method for forming the free layer 100, the tunneling barrier layer 200, the first spacer 300, the fixed layer 400, the second spacer 500, the first synthetic antiferromagnetic composite layer 600, the third spacer 700, the second synthetic antiferromagnetic composite layer 800, and the capping layer 900, other suitable formation methods may also be applied according to each material.

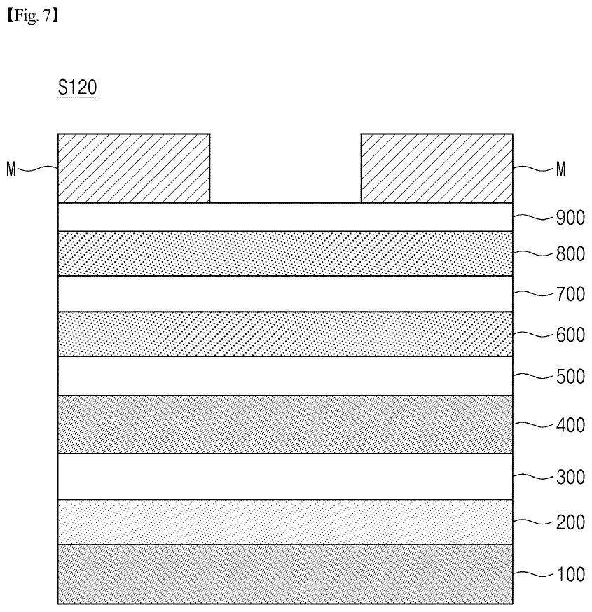

Referring to FIG. 7, after step S110, a mask M may be disposed on the stack structure (S120). According to one embodiment, the mask M may be disposed on the capping layer 900, and may expose a central region of the stack structure and cover an edge region of the stack structure.

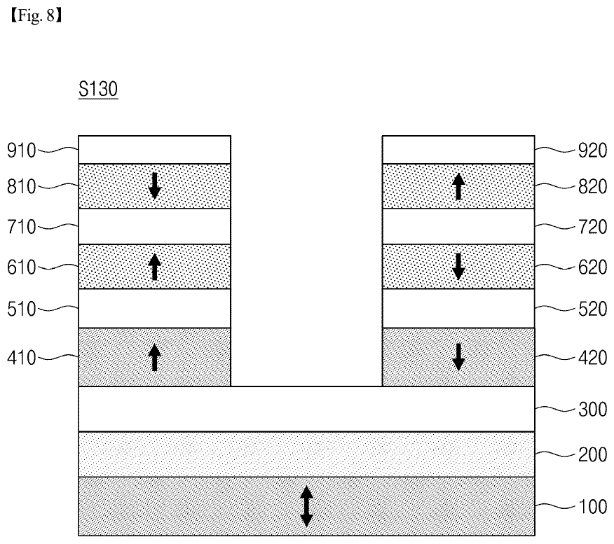

Referring to FIG. 8, after step S120, an etching process may be performed using the mask M (S130). More specifically, the central region of the stack structure, which is exposed by the mask M, may be etched. In addition, the capping layer 900, the second synthetic antiferromagnetic composite layer 800, the third spacer 700, the first synthetic antiferromagnetic composite layer 600, the second spacer 500, and the fixed layer 400 may be etched, whereas the first spacer 300, the tunneling barrier layer 200, and the free layer 100 may not be etched. Accordingly, the central region of the first spacer 300 may be exposed to the outside.

According to one embodiment, one side of the etched fixed layer 400 may be defined as the first fixed layer 410, and the other side of the etched fixed layer 400 may be defined as the second fixed layer 420. In addition, one side of the etched second spacer 500 may be defined as the 2-1^{st} spacer 510, and the other side of the etched second spacer 500 may be defined as the 2-2^{nd} spacer 520. In addition, one side of the etched first synthetic antiferromagnetic composite layer 600 may be defined as a 1-1^{st} synthetic antiferromagnetic composite layer 610, and the other side of the etched first synthetic antiferromagnetic composite layer 600 may be defined as a 1-2^{nd} synthetic antiferromagnetic composite layer 620. In addition, one side of the etched third spacer 700 may be defined as a 3-1^{st} spacer 710, and the other side of the etched third spacer 700 may be defined as a 3-2^{nd} spacer 720. In addition, one side of the etched synthetic antiferromagnetic composite layer 800 may be defined as a 2-1^{st} synthetic antiferromagnetic composite layer 810, and the other side of the etched synthetic antiferromagnetic composite layer 800 may be defined as a 2-2^{nd} synthetic antiferromagnetic composite layer 820. In addition, one side of the etched capping layer 900 may be defined as a first capping layer 910, and the other side of the etched capping layer 900 may be defined as a second capping layer 920.

Accordingly, the 2-1^{st} spacer 510, the 1-1^{st} synthetic antiferromagnetic composite layer 610, the 3-1^{st} spacer 710, the 2-1^{st} synthetic antiferromagnetic composite layer 810, and the first capping layer 910 may be sequentially disposed on the first fixed layer 410, and the 2-2^{nd} spacer 520, the 1-2^{nd} synthetic antiferromagnetic composite layer 620, the 3-2^{nd} spacer 720, the 2-2^{nd} synthetic antiferromagnetic composite layer 820, and the second capping layer 920 may be sequentially disposed on the second fixed layer 420.

According to one embodiment, the 1-1^{st} synthetic antiferromagnetic composite layer 610, the 3-1^{st} spacer 710, and the 2-1^{st} synthetic antiferromagnetic composite layer 810 may be defined as a first magnetization fixed structure. Alternatively, the 1-2^{nd} synthetic antiferromagnetic composite layer 620, the 3-2^{nd} spacer 720, and the 2-2^{nd} synthetic antiferromagnetic composite layer 820 may be defined as a second magnetization fixed structure.

The first magnetization fixed structure may fix magnetization of the first fixed layer 410. To this end, according to one embodiment, the 1-1^{st} synthetic antiferromagnetic composite layer 610 may have a magnetization direction parallel to the magnetization direction of the first fixed layer 410, whereas the 2-1^{st} synthetic antiferromagnetic composite layer 810 may have a magnetization direction opposite to the magnetization direction of the first fixed layer 410.

The second magnetization fixed structure may fix magnetization of the second fixed layer 420. To this end, according to one embodiment, the 1-2^{nd} synthetic antiferromagnetic composite layer 620 may have a magnetization direction parallel to the magnetization direction of the second fixed layer 420, whereas the 2-2^{nd} synthetic antiferromagnetic composite layer 820 may have a magnetization direction opposite to the magnetization direction of the second fixed layer 420.

After step S130, a heat treatment may be performed by applying an external magnetic field to the fixed layer 400 in which the central region is etched, that is, the first fixed layer 410 and the second fixed layer 420 (S140). For example, the first fixed layer 410 and the second fixed layer 420 may be heat-treated at a temperature of 350° C. to 400° C. under the application of the external magnetic field. Accordingly, the magnetization directions of the first fixed layer 410 and the second fixed layer 420 may be determined.

As described above, as the 2-1^{st} spacer 510 and the 2-2^{nd} spacer 520 have a thickness of 0.15 nm to 0.3 nm, strong ferromagnetic coupling may be provided between the first fixed layer 410 and the 1-1^{st} synthetic antiferromagnetic composite layer 610 and between the second fixed layer 420 and the 1-2^{nd} synthetic antiferromagnetic composite layer 620, respectively. In addition, as the 3-1^{st} spacer 710 and the 3-2^{nd} spacer 720 have a thickness of 0.85 nm, antiferromagnetic coupling may be provided between the 1-1^{st} synthetic antiferromagnetic composite layer 610 and the 2-1^{st} synthetic antiferromagnetic composite layer 810 and between the 1-2^{nd} synthetic antiferromagnetic composite layer 620 and the 2-2^{nd} synthetic antiferromagnetic composite layer 820, respectively. Thus, since coercive fields of the first fixed layer 410 and the second fixed layer 420 may increase, accidental switching of the first fixed layer 410 and the second fixed layer 420 may be prevented.

In describing the magnetic tunnel junction device according to the embodiment with reference to FIG. 1, although the first magnetization fixed structure and the second magnetization fixed structure, which are disposed on the 2-1^{st} spacer 510 and the 2-2^{nd} spacer 520, respectively, are omitted, the first magnetization fixed structure and the second magnetization fixed structure may be disposed on or omitted from the 2-1^{st} spacer 510 and the 2-2^{nd} spacer 520, respectively, depending on the specific application situation of the magnetic tunnel junction device.

Hereinabove, the method for manufacturing a magnetic tunnel junction device according to the embodiment of the present invention has been described. Hereinafter, specific experimental examples and characteristic evaluation results of the magnetic tunnel junction device according to the embodiment of the present invention will be described.

### Experimental Example 1: Simulation Verification of Switching Method

A magnetic tunnel junction device manufactured by the method described with reference to FIGS. 7 and 8 was prepared, and a switching method was verified through a micromagnetic simulation at MATLAB.

More specifically, a motion of a magnetization vector \vec{m} was modeled by a Landau-Lifshitz-Gilbert (LLG) equation according to <Equation 3> below:

$$\frac{d \vec{m}}{dt} = - \frac{{γ}_{0}}{( 1 + {α}^{2} )} [ \vec{m} \times {\vec{H}}_{eff} - \frac{α}{{γ}_{0}} \vec{m} \times \frac{d \vec{m}}{dt} - \frac{{PI}_{s} ℏ}{2 q {μ}_{0} {M}_{s} {V}_{fl}} \vec{m} \times ( \vec{m} \times {\vec{m}}_{pl} ) ] \qquad Equation 3$$

wherein the last term represents the STT, and since the applied current is small, the STT term is significantly lower than that of the field torque and thus may be ignored.

An effective magnetic field \vec{H}_{eff} may be expressed by Equation 4 below, and the total free energy density Eₜₒₜ may be expressed by magnetic anisotropy, VCMA, and demagnetization energy terms as in Equation 5 below.

$${\vec{H}}_{eff} = - \frac{1}{{μ}_{0} {M}_{s}} \frac{{dE}_{tot}}{d \vec{m}} + {\vec{H}}_{th} \qquad Equation 4$$

$${E}_{tot} = - \frac{{K}_{i}}{{t}_{fl}} {m}_{𝓏}^{2} + \frac{ξ {I}_{s} {R}_{MTJ}}{{t}_{fl} {t}_{ox}} {m}_{𝓏}^{2} + \frac{{M}_{s}^{2} {μ}_{0}}{2} ( {N}_{x} {m}_{x}^{2} + {N}_{y} {m}_{y}^{2} + {N}_{𝓏} {m}_{𝓏}^{2} ) \qquad Equation 5$$

The Brownian motion (irregularity according to temperature) \vec{H}ₜₕ of the magnetization may be expressed by Equation 6 below, and a resistance R_{MTJ} of magnetic tunnel junction may be modeled as in Equation 7 below.

$${\vec{H}}_{th} = \vec{σ} \sqrt{\frac{2 {k}_{B} T α}{{γ}_{0} {μ}_{0} {M}_{s} {V}_{fl} Δ t}} \qquad Equation 6$$

$${R}_{MTJ} = {R}_{p} \frac{1 + {( {V}_{ox} / {V}_{h} )}^{2} + TMR}{1 + {( {V}_{ox} / {V}_{h} )}^{2} + TMR [ 1 / 2 ( cos θ ) ]} \qquad Equation 7$$

In Equation 7, Rₚ denotes a resistance in a parallel state, and Vₕ denotes a voltage at which resistance in an anti-parallel state Rₐₚ becomes half.

### Experimental Example 2: Role Verification of First Spacer

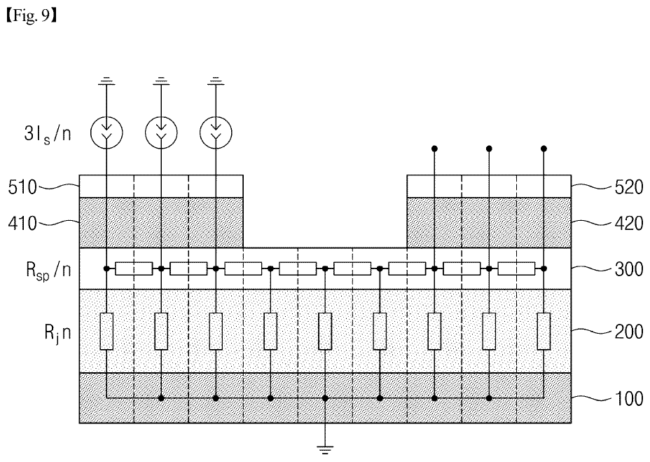

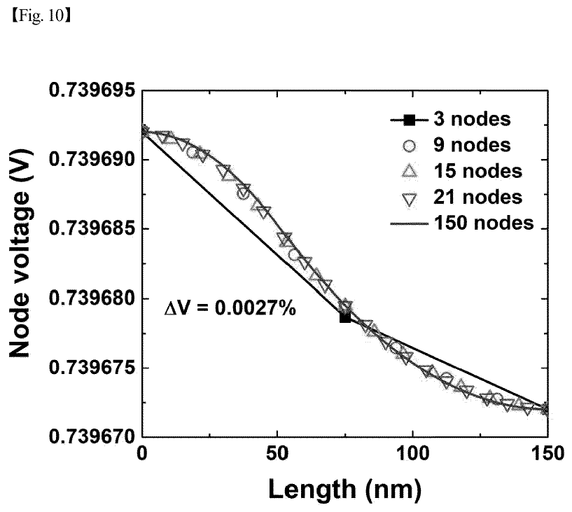

FIG. 9 is a view for explaining an equivalent resistance circuit of the magnetic tunnel junction device according to the embodiment of the present invention, and FIG. 10 is a view for explaining a voltage distribution in the magnetic tunnel junction device according to the embodiment of the present invention.

More specifically, FIG. 9 shows an equivalent circuit of a device for performing modeling, to which modified nodal analysis is applied, and FIG. 10 shows a voltage distribution in a horizontal direction when the first fixed layer is in an AP state and spin scattering is ignored (this assumption is valid because a device length (150 nm) is sufficiently smaller than a spin flip length (600 nm) of the first spacer). A junction resistance in a horizontal direction is Rⱼ=nR_{MTJ} and a resistance of the first spacer in a horizontal direction is Rₛₚ=ρL/t_{FL}Wn, wherein n is the number of nodes and resistivity of copper (Cu) ρ=1.72×10^{-S} Ω·m is used. As can be seen from FIG. 10, it can be seen that even if the number of nodes is reduced to 3, it is sufficient to accurately calculate the device Rⱼ>>Rₛₚ and is satisfied, so that it can be seen that a left and right potential difference ΔV is only 0.0027%. That is, it can be seen that the voltage is uniformly distributed by the first spacer. Therefore, in the subsequent analysis, a uniform Vₒₓ (voltage induced between the upper and lower ends of the tunneling barrier layer) is assumed.

### Experimental Example 3: Change Confirmation of Magnetization Direction

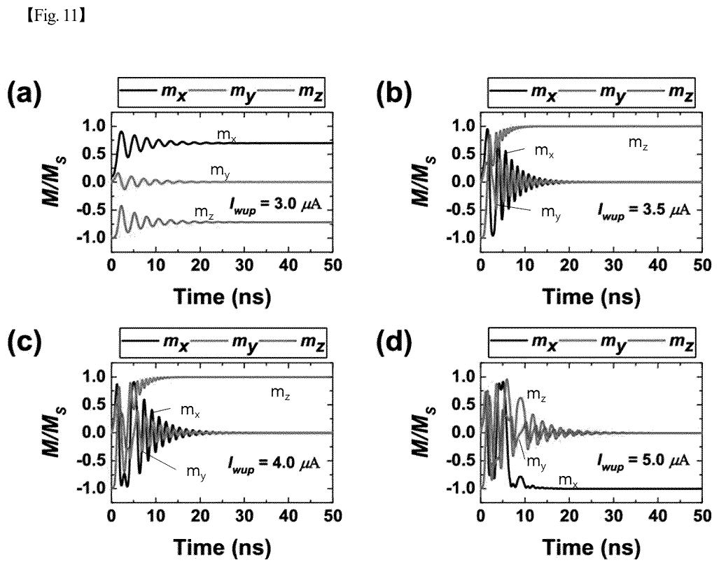

FIG. 11 is a view for explaining a change in a magnetization direction over time of the magnetic tunnel junction device according to the embodiment of the present invention.

Referring to FIG. 11, a movement of the magnetization direction when a current pulse (50 ns) is applied is shown (in this case, random thermal influence is ignored). Referring to FIG. 11A, it can be seen that a current (3 A) is insufficient for switching to occur. Thus, a level of the current may be used for a read operation. This induces a voltage (0.81 V) and the magnetization stabilizes at −0.75. Referring to FIG. 11B, it can be seen that a current (3.5 A) generates successful switching and a switching time is 4.6 ns. It can also be seen that a voltage during switching changes from the AP state (0.90 V) to a P state (0.48 V). Referring to FIG. 11C, it can be seen that switching occurs even at 4 A, and a voltage across the MTJ changes from 0.97 V to 0.55 V. However, it can be seen that the magnetization vibrates up and down and becomes the P state, and the switching time increases to 7 ns. Referring to FIG. 11D, it can be seen that a current (5 A) induces a voltage (1.12 V), but precession occurs and deterministic switching is no longer possible.

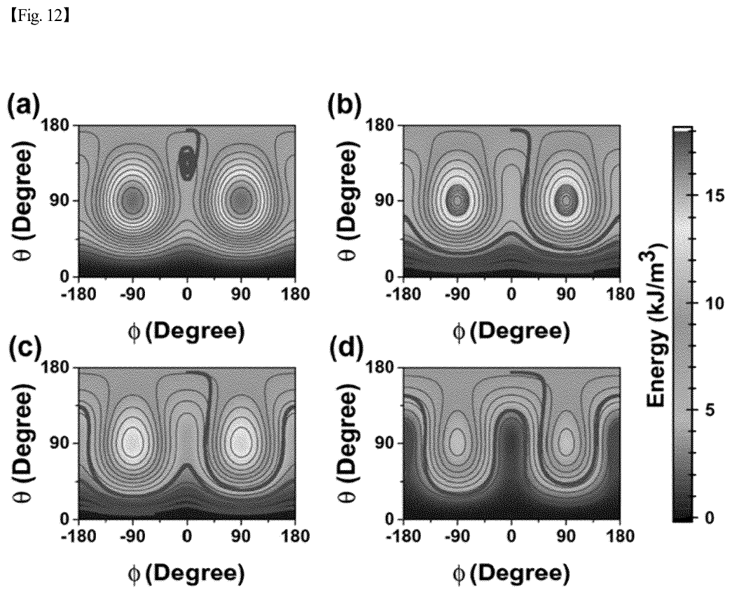

FIG. 12 is a view for explaining an energy contour map of the magnetic tunnel junction device according to the embodiment of the present invention.

Referring to FIG. 12, an energy contour map for explaining switching characteristics according to a current is shown. More specifically, an energy contour plot shows a trajectory of the magnetization in a θφ-plane. Referring to FIG. 12A, it can be seen that when a current is 3 A, there is a small energy barrier between the AP and P states to prevent switching. Referring to FIG. 12B, it can be seen that when a current is 3.5 A, the energy barrier disappears and a lowest energy point is θ=0°, so that the switching occurs. Referring to FIG. 12C, it can be seen that switching occurs similarly when a current is 4 A, and a local energy “pocket” is formed on an x-axis, and it can be seen that the switching time increases as the magnetization stays in the pocket. Referring to FIG. 12D, as a result, at a current of 5 A, the “pocket” becomes deep, and thus it can be confirmed that the magnetization vector is trapped. Therefore, it can be seen that an appropriate current magnitude needs to be used to prevent deep pocket formation. In order to increase a current range, an aspect ratio (AR) of the ferromagnetic material is reduced, but the switching time increases.

### Experimental Example 4: Performance Confirmation

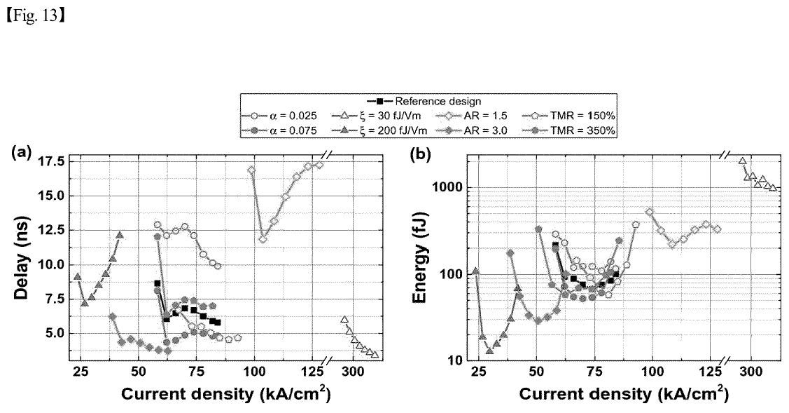

FIG. 13 is a view for explaining a switching time and switching energy of the magnetic tunnel junction device according to the embodiment of the present invention.

Referring to FIG. 13A, a linear scale according to a current density is shown, and referring to FIG. 13B, a log scale for each current density is shown. In addition, FIGS. 13A and 13B show a tendency (sensitivity) according to material variables.

More specifically, characteristic change and sensitivity analysis according to material variables were performed to optimize performance. The variables used as default are shown in <Table 1> (Reference design). A damping constant (attenuation constant), a VCMA coefficient, TMR, and AR were changed one by one. In this case, other variable values were fixed, but only interface anisotropy was changed to maintain a thermal stability factor at the same value. The switching time and switching energy values were obtained through Monte Carlo simulation to consider random thermal fluctuation. A critical value for determining that switching occurred was set to m_{z}=0.9. The final result is as shown in FIGS. 13A and 13B.

TABLE 1

| | | |
|---|---|---|
| Symbol | Value | Description |

| Mₛ | 6.25 × 10⁵ | A/m | Saturation magnetization |
|---|---|---|---|
| Δ | 60.0 | | Thermal stability factor |
| Kᵢ | 0.68 | mJ/m²* | Interfacial anisotropy constant |
| ξ | 100 | fJ/V · m | VCMA coefficient |
| α | 0.05 | | Damping constant |
| P | 0.58 | | Spin polarization |
| L × W | 110 × 50 | nm² | Area of MTJ |
| t_{f} | 3.0 | nm | Thickness of th FL |
| tₒₓ | 1.65 | nm | Oxide thickness |
| RAₚ | 758.7 | Ω · μm² | Resistance-area product |
| TMR | 250% | | Tunneling magnetoresistance |
| Vₕ | 0.65 | V | Voltage at which Rₐₚ halves |

### Experimental Example 5: Comparison with Different Switching Technologies

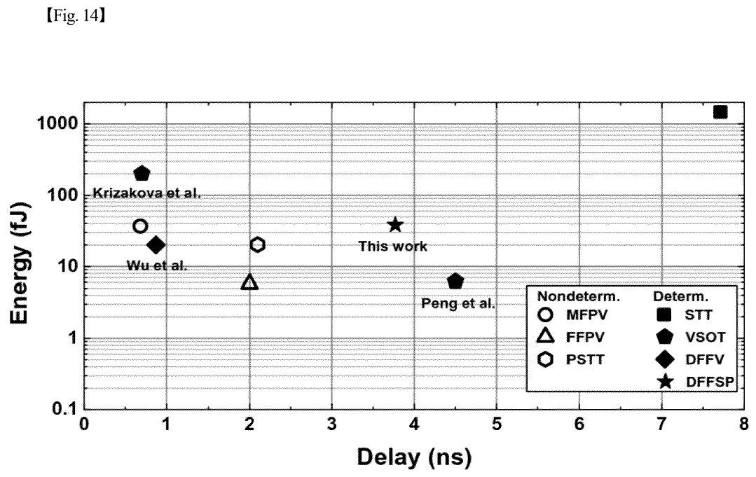

FIG. 14 is a view for comparing the magnetic tunnel junction device according to the embodiment of the present invention with devices having different switching methods.

FIG. 14 shows performance comparison and benchmarking results with different magnetic material switching technologies. The STT switching consumes the most energy with an average switching time of 7.74 ns and an average write energy of 1470 fJ. The MFPV has a delay of 0.68 ns and is the fastest of the compared methods, but the energy is 36.80 fJ (the energy consumed in the MTJ is ~1.8 fJ, which is only a part). The FFPV method has a delay of 2.0 ns and is several times slower than a method assisted by a magnetic field, but has the advantage of low energy consumption of 6.22 fJ. The PSTT method has a delay of 2.10 ns and energy of 22.31 fJ. The VSOT method takes two approaches into account: Peng et al. (IEEE IEDM 2019) showed a delay of 4.5 ns and energy of 6.2 fJ, and Krizakova et al. (APL 2020) reported a low delay of 0.7 ns, but did not mention switching energy, and when a relatively large current density is considered, an estimated energy loss is about 200 fJ. Wu et al. (Symp. VLSI 2020) reported DFFV MTJ switching with a delay of 0.87 ns and energy of 20 fJ. A magnetic tunnel junction device DFFSP according to the embodiment of the present invention may be slower with a delay of 3.77 ns and energy of 38.22 fJ compared to the conventional switching method without a magnetic field, but a single pulse operation without a pre-read may compensate for a difference between the delay and the energy. Since a simple comparison in terms of delay and energy presents an incomplete picture, a more detailed comparison is shown in <Table 2>.

TABLE 2

| | | | | | | | DFFSP |
|---|---|---|---|---|---|---|---|
| | | | | | | | (Present |
| Classification | STT | MFPV | FFPV | PSTT | VSOT | DFFV | invention) |
| Delay (ns) | 7.74 | 0.68 | 2.0 | 2.1 | 4.5/0.7 | 0.87 | 3.77 |
| Energy | 1470 | 36.8 | 6.22 | 22.31 | 6.2/200 | 20 | 38.22 |
| (fJ) | | | | | | | |
| Current | 4.6 | 0.09 (MTJ)/ | 0.09 | 0.33 | 5/170 | — | 0.06 |
| density | | 437 (wire) | | | | | |
| (MA/cm²) | | | | | | | |
| Pre-read | Not | Essential | Essential | Essential | Not | Not | Not |
| | needed | | | | needed | needed | needed |
| Pulse | Not | Essential | Essential | Two | Two | Two | Not |
| timing | needed | | | pulses | pulses | pulses | needed |
| control | | | | (consecutive) | (consecutive) | (consecutive) | |
| ExMF | No | 20 | No* | No* | NO* | NO** | NO |
| (kA/m) | | | | | | | |
| WER | <10⁻⁹ | 10⁻⁶ | 4.5 · 10⁻³ | <10⁻⁴ | — | ~10⁻⁴ | <10⁻⁹ |

(*Small bias field Hₓ = 4 kA/m provided from the antiferromagnetic stack to assist switching, **Small stray field Hₓ = 4 kA/m provided from the permanent magnet) Although the delay of the magnetic tunnel junction device DFFSP according to the embodiment of the present invention is not lower than that of other VCMA switching methods, it can be seen that the WER may be significantly reduced and the dependency on error correction circuit may be reduced because a pre-read operation or a precision pulse timing is not required. Similarly, compared to the STT (commercialized technology) that does not require a pre-read and a pulse timing control, the magnetic tunnel junction device DFFSP according to the embodiment of the present invention has a switching time twice faster and switching energy 38 times lower than those of the STT, and thus deterministic switching is possible with a low operating current density, and thus it can be seen that it is a technology suitable for high-precision and low-power memory applications.

While the present invention has been described in connection with the embodiments, it is not to be limited thereto but will be defined by the appended claims. In addition, it is to be understood that those skilled in the art may substitute, change, or modify the embodiments in various forms without departing from the scope and spirit of the present invention.

What is claimed is:

1. A magnetic tunnel junction device comprising:
a free layer having a magnetization direction that is switchable;
a tunneling barrier layer disposed on the free layer and including a metal oxide;
a first fixed layer disposed on the tunneling barrier layer and having a magnetization direction fixed in a first direction; and
a second fixed layer disposed on the tunneling barrier layer to be spaced apart from the first fixed layer, and having a magnetization direction fixed in a second direction that is opposite to the first direction.

2. The magnetic tunnel junction device of claim 1, wherein, when a current flows from the first fixed layer to the free layer, the magnetization direction of the free layer is switched to be parallel to the magnetization direction of the first fixed layer, and
when the current flows from the second fixed layer to the free layer, the magnetization direction of the free layer is switched to be parallel to the magnetization direction of the second fixed layer.

3. The magnetic tunnel junction device of claim 1, wherein, when a current flows from the first fixed layer or the second fixed layer to the free layer,
a voltage is induced between a first boundary surface, which is defined as a boundary surface between the free layer and the tunneling barrier layer, and a second boundary surface, which is defined as a boundary surface between the first fixed layer or the second fixed layer and the tunneling barrier layer, so that the magnetization direction of the free layer is switched, in accordance with Equation 1 below.
$${V}_{ox} = {I}_{s} {R}_{MTJ} \qquad Equation 1$$
(Vₒₓ: Voltage induced between the first boundary surface and the second boundary surface, Iₛ: Current flowing from the first fixed layer or the second fixed layer to the free layer, and R_{MTJ}: Resistance of the tunneling barrier layer)

4. The magnetic tunnel junction device of claim 3, wherein, when the voltage is induced between the first boundary surface and the second boundary surface, magnetic anisotropy energy of the first boundary surface, which is calculated according to <Equation 2> below, is reduced so that the magnetization direction of the free layer is switched.
$$Δ E = \frac{ξ}{{t}_{fl}} \frac{{V}_{ox}}{{t}_{ox}} \qquad Equation 2$$
(ΔE: Magnetic anisotropy energy reduction of the first boundary surface, ξ: Voltage-controlled magnetic anisotropy coefficient, t_{fl}: Thickness of the free layer, Vₒₓ: Voltage induced between the first boundary surface and the second boundary surface, tₒₓ: Thickness of the tunneling barrier layer)

5. The magnetic tunnel junction device of claim 4, wherein, as the magnetic anisotropy energy of the first boundary surface is reduced, energy asymmetry is formed between the free layer and the first fixed layer or between the free layer and the second fixed layer.

6. The magnetic tunnel junction device of claim 1, wherein a read operation is performed to confirm the magnetization direction of the free layer by flowing a current lower than a critical current, which switches the magnetization direction of the free layer, from the first fixed layer to the free layer.

7. The magnetic tunnel junction device of claim 1, further comprising a spacer disposed on the tunneling barrier layer and including a metal,
wherein the first fixed layer and the second fixed layer are disposed on the spacer to be spaced apart from each other.

8. The magnetic tunnel junction device of claim 7, wherein the spacer includes one of copper (Cu) and ruthenium (Ru).

9. The magnetic tunnel junction device of claim 1, wherein the free layer, the first fixed layer, and the second fixed layer include one of cobalt nickel (CoNi), cobalt iron boride (CoFeB), cobalt chromium (CoCr), cobalt iron (CoFe), cobalt platinum (CoPt), iron platinum (FePt), iron boride (FeB), cobalt boride (CoB), and cobalt iron aluminum (CeFeAl).

10. The magnetic tunnel junction device of claim 1, wherein the tunneling barrier layer includes one of magnesium oxide (MgO), aluminum oxide (Al₂O₃), magnesium aluminum oxide (MgAlO), hafnium oxide (HfO₂), zirconium oxide (ZrO₂), zinc oxide (ZnO₂), and titanium oxide (TiO₂).

11. A magnetic tunnel junction device comprising:
a first magnetic tunnel junction structure including a free layer having a magnetization direction that is switchable, a tunneling barrier layer disposed on the free layer, a spacer disposed on the tunneling barrier layer, and a first fixed layer disposed on the spacer and having a magnetization direction fixed in a first direction; and
a second magnetic tunnel junction structure including the free layer, the tunneling barrier layer, the spacer, and a second fixed layer disposed on the tunneling barrier layer and having a magnetization direction fixed in a second direction,
wherein the first magnetic tunnel junction structure and the second magnetic tunnel junction structure share the free layer, the tunneling barrier layer, and the spacer.

12. The magnetic tunnel junction device of claim 11, wherein the magnetization direction of the free layer is switched to the first direction or the second direction according to one of a case where a current flows from the first fixed layer to the free layer and a case where the current flows from the second fixed layer to the free layer.

13. The magnetic tunnel junction device of claim 12, wherein, when the current flows from the first fixed layer to the free layer, the magnetization direction of the free layer is switched to the first direction, and
when the current flows from the second fixed layer to the free layer, the magnetization direction of the free layer is switched to the second direction.

14. A method for manufacturing a magnetic tunnel junction device, the method comprising:
preparing a stack structure in which a free layer including a ferromagnetic material, a tunneling barrier layer including an oxide, a spacer including a metal, and a fixed layer including a ferromagnetic material are sequentially stacked;
providing a mask on the fixed layer, in which the mask exposes a central region of the fixed layer and covers an edge region of the fixed layer; and
exposing the spacer to an outside through the central region of the fixed layer by etching the central region of the fixed layer using the mask.

15. The magnetic tunnel junction device of claim 14, further comprising performing a heat treatment by applying an external magnetic field to the fixed layer in which the central region is etched, after the exposing of the spacer to the outside through the central region of the fixed layer by etching the central region of the fixed layer using the mask.
